(19) United States
(12) Patent Application Publication
(10) Pub. No.: US 2026/0231693 A1
(43) Pub. Date: Aug. 6, 2026

(54) VARIABLE RESISTIVE SEMICONDUCTOR MEMORY DEVICE HAVING A BARRIER LAYER

(71) Applicant: SK hynix Inc., Icheon-si (KR)

(72) Inventor: Young Jae KWON, Icheon-si (KR)

(21) Appl. No.: 19/330,223

(22) Filed: Sep. 16, 2025

(30) Foreign Application Priority Data
Feb. 3, 2025 (KR) 10-2025-0013058

(51) Int. Cl. H10N 70/00; H10B 63/00; H10N 70/20

(52) U.S. Cl. CPC H10N 70/828; H10B 63/80; H10N 70/011; H10N 70/24; H10N 70/8265

(57) ABSTRACT

A semiconductor device including a memory cell is disclosed. The memory cell includes a lower electrode; a variable resistance layer over the lower electrode; an oxygen reservoir layer over the variable resistance layer; and an upper electrode over the oxygen reservoir layer. The variable resistance layer includes a barrier layer; and a switching layer. The barrier layer includes a barrier framework layer having pores; and a barrier sidewall layer conformally formed on sidewalls of the pores of the barrier framework layer. The switching layer is formed over the barrier layer to fill the pores.

### CROSS-REFERENCE TO RELATED APPLICATION

The present application claims priority under 35 U.S.C § 119(a) to Korean Patent Application No. 10-2025-0013058, filed on Feb. 3, 2025, in the Korean Intellectual Property Office, which is incorporated herein by reference in its entirety.

### BACKGROUND

### 1. Field

The present disclosure is directed to a variable resistive semiconductor memory device and a method of manufacturing the variable resistive semiconductor memory device.

### 2. Description of the Related Art

A variable resistive semiconductor memory device configured to store data using a variable resistive layer with switching characteristics. Devices have been proposed in which the variable resistive layer switches between different resistance states depending on voltage or current.

### SUMMARY

An embodiment of the present disclosure is directed to a variable resistance layer with a lateral barrier layer that blocks diffusion of oxygen vacancies in a lateral direction.

An aspect of the present disclosure is directed to a semiconductor memory device having the variable resistance layer.

An aspect of the present disclosure is directed to a method of forming the variable resistance layer.

An aspect of the present disclosure is directed to a method of manufacturing a semiconductor memory having the variable resistance layer.

In accordance with an embodiment of the present disclosure, a semiconductor device includes a memory cell. The memory cell includes a lower electrode; a variable resistance layer over the lower electrode; an oxygen reservoir layer over the variable resistance layer; and an upper electrode over the oxygen reservoir layer. The variable resistance layer includes a barrier layer; and a switching layer. The barrier layer includes a barrier framework layer having pores; and a barrier sidewall layer conformally disposed on sidewalls of the pores of the barrier framework layer. The switching layer is disposed over the barrier layer to fill the pores.

In accordance with an embodiment of the present disclosure, a method of manufacturing a semiconductor device includes forming a lower electrode, forming a barrier layer having pores over the lower electrode, forming a switching layer over the barrier layer to fill the pores, forming an oxygen reservoir layer over the switching layer, and forming an upper electrode over the oxygen reservoir layer. Forming the barrier layer includes forming a barrier framework layer defining the pores over the lower electrode, and forming a barrier sidewall layer on sidewalls of the barrier framework layer in the pores.

### BRIEF DESCRIPTION OF THE DRAWINGS

FIGS. 1A and 1B are a circuit diagram and a perspective view schematically illustrating a semiconductor memory device according to an embodiment of the present disclosure.

FIG. 2A is a longitudinal cross-sectional view taken along line I-I′ of FIG. 1B to schematically illustrate a memory cell structure of a semiconductor memory device according to an embodiment of the present disclosure, and FIG. 2B is an enlarged view of the area A of FIG. 2A.

FIGS. 3A and 3B are plan views taken along line II-II′ of FIG. 2B to illustrate a barrier layer according to embodiments of the present disclosure.

FIGS. 4A, 5A, and 6 are plan views illustrating a structure of the barrier framework layer 41 of FIGS. 3A and 3B according to embodiments of the present disclosure. FIG. 4B is an enlarged view of an area B in FIG. 4A, and FIG. 5B is an enlarged view of an area C in FIG. 5A.

FIG. 7 is a longitudinal cross-sectional view schematically illustrating filaments formed in a variable resistance layer according to embodiments of the present disclosure.

FIGS. 8 to 13 and FIGS. 14 to 16 are longitudinal cross-sectional views illustrating methods of forming a memory cell structure of a semiconductor memory device according to embodiments of the present disclosure.

### DETAILED DESCRIPTION

Embodiments of the present disclosure are described in detail with reference to the accompanying drawings. Specific structural or functional descriptions of embodiments are provided as examples to describe concepts that are disclosed in the present application. Examples or embodiments in accordance with the concepts may be carried out in various forms, and the scope of the present disclosure is not limited to the examples or embodiments described in this specification.

The cross-hatching throughout the figures illustrates corresponding or similar areas between the figures rather than indicating the materials associated with the areas.

When one element is identified as “connected” or “coupled” to another element, the elements may be connected or coupled directly or through one or more intervening elements. When two elements are identified as “directly connected” or “directly coupled,” one element is directly connected or directly coupled to the other element without any intervening element.

When one element is identified as “on,” “over,” “under,” or “beneath” another element, the elements may directly contact each other or an intervening element may be disposed between the elements.

Terms such as “vertical,” “horizontal,” “top,” “bottom,” “above,” “below,” “under,” “beneath,” “over,” “on,” “side,” “upper,” “uppermost,” “lower,” “lowermost,” “front,” “rear,” “left,” “right,” “column,” “row,” “level,” and other terms implying relative spatial relationship or orientation are utilized only for the purpose of ease of description or reference to a drawing and are not otherwise to limit scope. Other spatial relationships or orientations not shown in the drawings or described in the specification are possible within the scope of the present disclosure.

Terms such as “first” and “second” are used to distinguish between various elements and do not imply size, order, priority, quantity, or importance of the elements. For example, a first element may be named as a second element in one example, and the second element may be named as a first element in another example.

In the description, when an element included in an embodiment is described in singular form, the element may be interpreted to include a plurality of elements performing the same or similar functions.

Concepts are disclosed in conjunction with examples and embodiments as described hereunder. Those skilled in the art will understand that various modifications, additions, and substitutions are possible without departing from the scope and technical concepts of the present disclosure. The embodiments disclosed in the present specification should be considered from an illustrative standpoint and not a restrictive standpoint. Therefore, the scope of the present disclosure is not limited to the descriptions below. All changes within the meaning and range of equivalency of the claims are included within their scope.

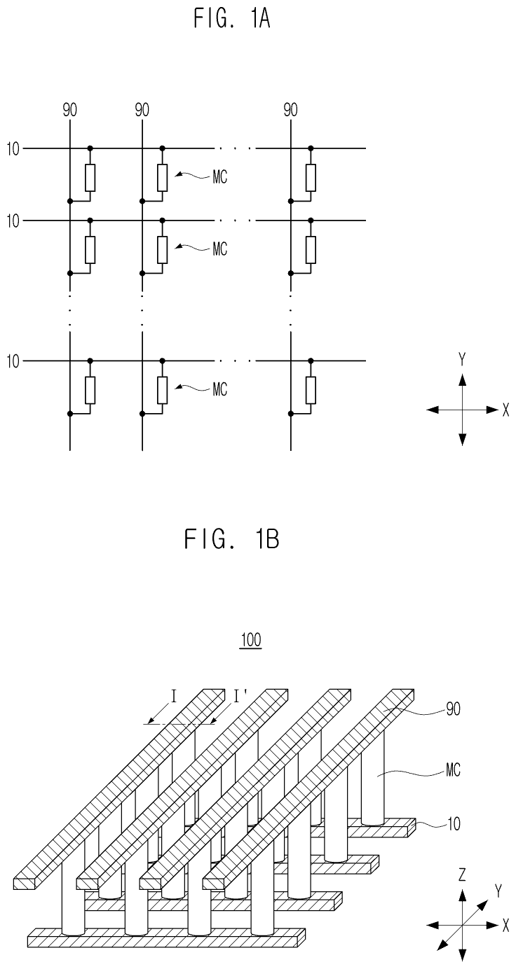

FIGS. 1A and 1B are a circuit diagram and a perspective view schematically illustrating a semiconductor memory device according to an embodiment of the present disclosure. Referring to FIGS. 1A and 1B, a semiconductor memory device 100 may include lower interconnection lines 10, upper interconnection lines 90, and memory cells MC. The lower interconnection lines 10 may extend parallel to each other in a first horizontal direction X. The lower interconnection lines 10 may correspond to word lines. The upper interconnection lines 90 may extend parallel to each other in a second horizontal direction Y. The upper interconnection lines 90 may correspond to bit lines. In another embodiment, the lower interconnection lines 10 may correspond to the bit lines, and the upper interconnection lines 90 may correspond to the word lines. The first horizontal direction X and the second horizontal direction Y may be perpendicular to each other. The memory cells MC may be disposed at intersections between the lower interconnection lines 10 and the upper interconnection lines 90, respectively, from a plan view and include a first electrode and a second electrode. Each of the memory cells MC may have a vertical pilar shape. First electrodes of the memory cells MC may be electrically connected to the lower interconnection lines 10, and second electrodes of the memory cells MC may be electrically connected to the upper interconnection lines 90, respectively.

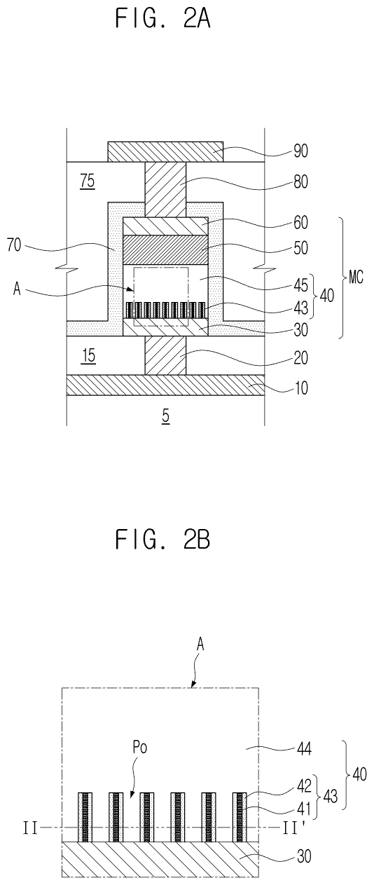

FIG. 2A is a longitudinal cross-sectional view taken along line I-I′ of FIG. 1B to schematically illustrate a memory cell structure of a semiconductor memory device according to an embodiment of the present disclosure, and FIG. 2B is an enlarged view of the area A of FIG. 2A. Referring to FIGS. 2A and 2B, the memory cell structure of the semiconductor memory device may include a lower interconnection line 10, a lower contact plug 20, a memory cell MC, an upper contact plug 80, and an upper interconnection line 90, which are sequentially stacked and disposed in a vertical direction on an underlying layer 5. The memory cell MC may include a lower electrode 30, a variable resistance layer 40, an oxygen reservoir layer 50, and an upper electrode 60. The memory cell structure may include the lower contact plug 20, the memory cell MC, the upper contact plug 80, and further include a lower interlayer insulating layer 15, a spacer layer 70, and an upper interlayer insulating layer 75.

The underlying layer 5 may include a substrate or an insulating layer disposed on the substrate. In an embodiment, the underlying layer 5 may include one of a silicon wafer, an epitaxially grown single crystalline silicon layer, a silicon compound layer such as a silicon germanium compound, or a compound semiconductor layer such as a gallium arsenide layer or an aluminum gallium arsenide layer. For example, the underlying layer 5 may include at least one of silicon oxide-based insulating layers or silicon nitride-based insulating layers.

The lower interconnection line 10 may be disposed on the underlying layer 5. The lower interconnection line 10 may include a metal such as tungsten, a metal nitride such as titanium nitride, a metal silicide, an alloy, or other conductive material.

The lower contact plug 20 may be disposed between the lower interconnection line 10 and the lower electrode 30 of the memory cell MC. The lower contact plug 20 may electrically connect the lower interconnection line 10 to the lower electrode 30 of the memory cell MC. The lower contact plug 20 may include at least one of doped polycrystalline silicon, a metal, a metal alloy, a metal compound, or a metal silicide. In an embodiment, the lower contact plug 20 may include at least one of tungsten or titanium nitride.

The lower interlayer insulating layer 15 may cover an upper surface of the lower interconnection line 10 and may surround side surfaces of the lower contact plug 20. The lower interlayer insulating layer 15 may include a silicon oxide-based insulating layer.

The lower electrode 30 may be disposed on the lower contact plug 20 and the lower interlayer insulating layer 15. The lower electrode 30 may include a diffusion barrier material for blocking diffusion of oxygen atoms or oxygen ions. The lower electrode 30 may include a metal nitride such as titanium nitride.

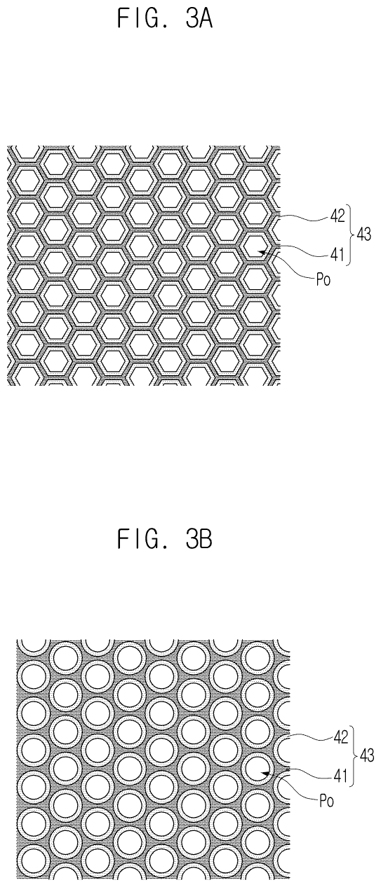

The variable resistance layer 40 may be disposed on the lower electrode 30. The variable resistance layer 40 may include a barrier layer 43 having vertical pores Po and a switching layer 44 on the barrier layer 43. Referring to FIG. 2B, the barrier layer 43 may include a barrier framework layer 41 and a barrier sidewall layer 42. In a longitudinal cross-sectional view or in a side view, the barrier framework layer 41 may appear as walls or have wall-like shapes. The barrier framework layer 41 will be described in more detail with reference to FIGS. 3A and 3B, 4A and 4B, 5A and 5B, and FIG. 6. The barrier sidewall layer 42 may be conformally formed on sidewalls of the barrier framework layer 41. The barrier sidewall layer 42 may block movement or diffusion of oxygen ions or oxygen vacancies. The barrier sidewall layer 42 may be an insulating material layer that does not include oxygen or include negligible—for example, less than 0.1 at %—oxygen. For example, the barrier sidewall layer 42 may include a silicon nitride layer or a silicon nitride-based insulating material layer. Upper ends of the barrier framework layer 41 may be exposed without being covered by the barrier sidewall layer 42. In some embodiments however, the barrier sidewall layer 42 may cover the upper ends of the barrier framework layer 41.

A lower portion of the switching layer 44 may fill the pores Po. The switching layer 44 may include a transition metal oxide layer. For example, the switching layer 44 may include at least one of a titanium oxide layer, a vanadium oxide layer, a manganese oxide layer, an iron oxide layer, a cobalt oxide layer, a zinc oxide layer, a yttrium oxide layer, a zirconium oxide layer, a niobium oxide layer, a molybdenum oxide layer, a ruthenium oxide layer, a palladium oxide layer, a barium oxide layer, a lanthanum oxide layer, a hafnium oxide layer, an iridium oxide layer, or other transition metal oxide layers. In an embodiment, the switching layer 44 may include a hafnium oxide layer.

The oxygen reservoir layer 50 may be disposed on the variable resistance layer 40. The oxygen reservoir layer 50 may provide oxygen ions to the variable resistance layer 40 or absorb oxygen ions from the variable resistance layer 40. The oxygen reservoir layer 50 may include a metal layer or a metal oxide layer. For example, the oxygen reservoir layer 50 may include at least one of a tantalum layer, a hafnium layer, a zirconium layer, a titanium layer, a tantalum oxide layer, a hafnium oxide layer, a zirconium oxide layer, or a titanium oxide layer.

The upper electrode 60 may be disposed on the oxygen reservoir layer 50. The upper electrode 60 may include a diffusion barrier material for blocking diffusion of oxygen ions. The upper electrode 60 may include a metal nitride such as titanium nitride.

Side surfaces of the lower electrode 30, the variable resistance layer 40, the oxygen reservoir layer 50, and the upper electrode 60 may be vertically aligned with each other and coplanar sidewalls in the vertical direction.

The spacer layer 70 may be conformally disposed on an upper surface of the lower interlayer insulating layer 15, side surfaces of the lower electrode 30, side surfaces of the variable resistance layer 40, side surfaces of the oxygen reservoir layer 50, side surfaces of the upper electrode 60, and an upper surface of upper electrode 60. The spacer layer 70 may space apart the lower interlayer insulating layer 15, the lower electrode 30, the variable resistance layer 40, the oxygen reservoir layer 50, and the upper electrode 60 from the upper interlayer insulating layer 75. The spacer layer 70 may include an insulating material that does not include oxygen or include negligible oxygen. For example, the spacer layer 70 may include one of silicon nitride-based insulating layers such as a silicon nitride layer, a silicon boron nitride layer, or a silicon carbon nitride layer. The spacer layer 70 may block movement and diffusion of oxygen ions or oxygen vacancies.

The upper interlayer insulating layer 75 may be disposed on the lower interlayer insulating layer 15 to surround side surfaces of the lower electrode 30, the variable resistance layer 40, the oxygen reservoir layer 50, the upper electrode 60, and the upper contact plug 80. An upper surface of the upper interlayer insulating layer 75 and an upper surface of the upper contact plug 80 may be coplanar. In an embodiment, the upper interlayer insulating layer 75 may include an insulating material layer such as a silicon oxide layer.

The upper contact plug 80 may vertically pass through the spacer layer 70 and the upper interlayer insulating layer 75 to electrically connect the upper electrode 60 to the upper interconnection line 90. The upper contact plug 80 may include at least one of doped polycrystalline silicon, a metal, a metal alloy, a metal compound, or a metal silicide. In an embodiment, the upper contact plug 80 may include tungsten or titanium nitride.

The upper interconnection line 90 may be disposed on the upper contact plug 80. The upper interconnection line 90 may include a metal such as tungsten, a metal nitride such as titanium nitride, a metal silicide, an alloy, or other conductive material.

FIGS. 3A and 3B are plan views taken along line II-II′ of FIG. 2B to illustrate a barrier layer according to embodiments of the present disclosure. Referring to FIG. 3A, a barrier layer 43 may have a two-dimensional hexagonal honeycomb-shaped structure. Referring to FIG. 3B, the barrier layer 43 may have a structure of circular rings arranged in a two-dimensional zigzag form or in offset rows. In FIGS. 3A and 3B, the barrier layer 43 may include a barrier framework layer 41 defining a plurality of pores Po, and a barrier sidewall layer 42 formed on sidewalls of the barrier framework layer 41 that define the pores Po.

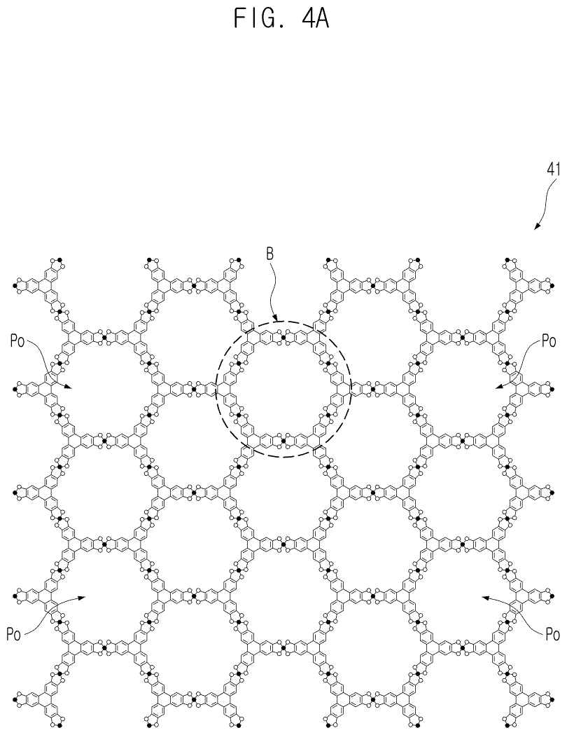

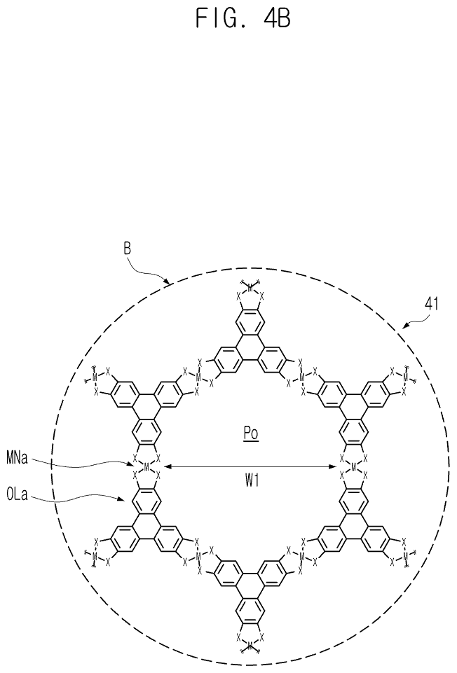

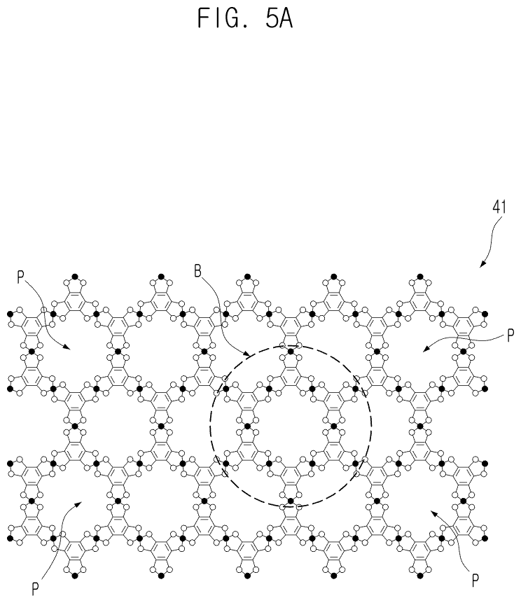

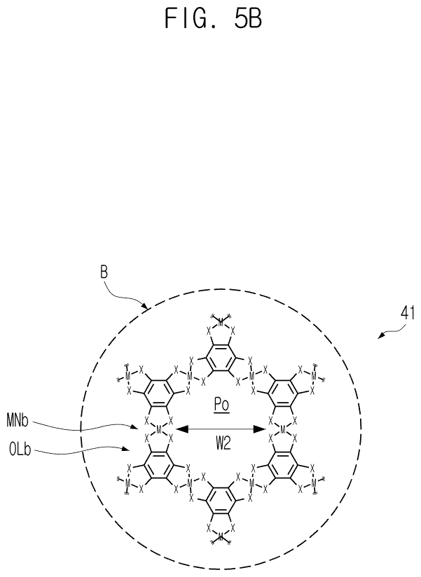

FIGS. 4A, 5A, and 6 are plan views illustrating a structure of the barrier framework layer 41 of FIGS. 3A and 3B according to embodiments of the present disclosure. FIG. 4B is an enlarged view of an area B in FIG. 4A, and FIG. 5B is an enlarged view of an area C in FIG. 5A. Referring to FIGS. 4A and 4B to 5A and 5B, the barrier framework layer 41 may include a metal-organic framework layer. Tn an embodiment, the barrier framework layer 41 may include a metal and triphenylene compound. The metal-organic framework layer may include metal nodes MNa and MNb and organic ligands OLa and OLb. Each of the metal nodes MNa and MNb may include a metal ion or a metal cluster. The organic ligands OLa and OLb may include a hexatriphenylene compound.

Referring to FIGS. 4A and 4B, the barrier framework layer 41 may include [M₃(HXTP)₂] (where, M is metal, H is hexa, X is one of oxygen (O), sulfur (S), and imine (NH), and TP is triphenylene). In an embodiment, when X is oxygen (O), the barrier framework layer 41 may include [M₃(HHTP)₂] (metal hexahydroxytriphenylene). In an embodiment, when X is sulfur (S), the barrier framework layer 41 may include [M₃(HSTP)₂] (metal hexasulfurotriphenylene). In an embodiment, when X is an imine (NH), the barrier framework layer 41 may include [M₃(HITP)₂] (metal hexaiminotriphenylene). In an embodiment, the metal M may be one of cobalt (Co), nickel (Ni), or copper (Cu), and X may be oxygen (O). In another embodiment, the metal M may be one of iron (Fe), cobalt (Co), or platinum (Pt), and X may be sulfur (S). In another embodiment, the metal M may be one of Cobalt (Co), Nickel (Ni), or Copper (Cu), and X may be imine (NH).

Referring to FIGS. 5A and 5B, the barrier framework layer 41 may include [M₃(HXB)₂] (where, M is metal, H is hexa, X is one of oxygen (O), sulfur (S), and imine (NH), and B is benzene). In an embodiment, when X is oxygen (O), the barrier framework layer 41 may include [M₃(HHB)₂] (metal hexahydroxybenzene). When X is sulfur (S), the barrier framework layer 41 may include [M₃(HSB)₂] (metal hexasulfurobenzene). When X is imine (NH), the barrier framework layer 41 may include [M₃(HIB)₂] (metal hexaiminobenzene).

In an embodiment, the metal M may be copper (Cu), and X may be oxygen (O). In another embodiment, the metal M may be one of nickel (Ni) or palladium (Pd), and X may be sulfur(S). In another embodiment, the metal M may be one of manganese (Mn), cobalt (Co), nickel (Ni), or copper (Cu), and X may be imine (NH).

In embodiments, the organic ligands Ola and OLb may include at least one of oxalic acid, fumaric acid, benzenehexathiol, triphenylenehexathiol, 1,4-benzene dicarboxylic acid, hexaaminobenzene, tetrakis(4-carboxyphenyl)-porpyrinato-cobalt(II), tetrakis(4-carboxyphenyl)-porphorphyrin, 1,4-dioxydicarboxyphenyl-2,5-benzenedicarboxylate, H₂BDC, H₂BDC—Br, H₂BDC—OH, H₂BDC—NO2, H₂BDC—NH₂, H₄DOT, H₂BDC—(Me)₂, or H₂BDC—(Cl)₂.

Referring to FIGS. 4A, 4B, 5A and 5B, widths W1 and W2 of the pores Po may be variously set and selected according to a material. For example, the triphenylene ring structure of FIG. 4B may have a first width W1, and the benzene structure of FIG. 5B may have a second width W2. Since the triphenylene ring structure has more ring bonds than the benzene ring structure, the first width W1 of the triphenylene ring structure may be greater than the second width W2 of the benzene ring structure. That is, the widths of the pores Po of the barrier framework layer 41 may be set and selected according to a combination of various materials.

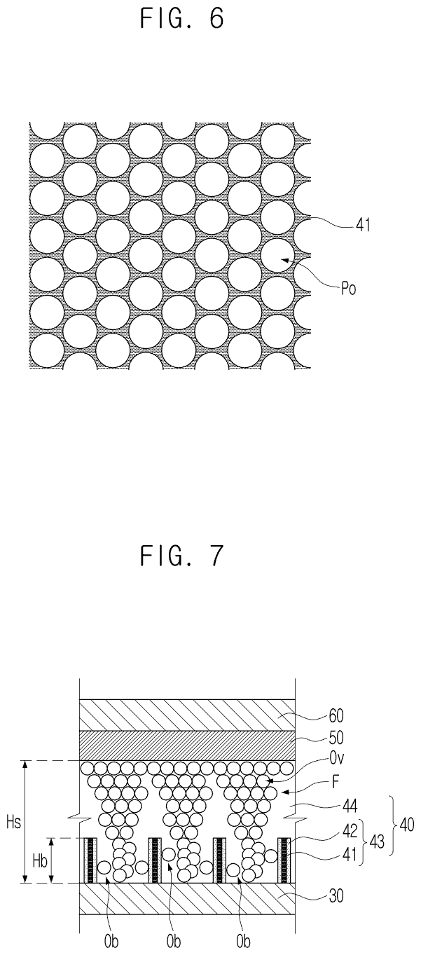

FIG. 6 is a plan view illustrating a structure of the barrier framework layer 41 of FIG. 3B. Referring to FIG. 6, the barrier framework layer 41 may include a polymeric material layer such as a polymethyl methacrylate (PMMA) layer or a block-co-polymer layer. In another embodiment, the barrier framework layer 41 may have a 2-dimensionally arranged polygon structure. The polygon structure may include circular rings having pores Po arranged in a zigzag form, in which rows of circular rings and pore Po are offset relative to each other.

FIG. 7 is a longitudinal cross-sectional view schematically illustrating filaments formed in a variable resistance layer according to embodiments of the present disclosure. Referring to FIG. 7, filaments F may be formed in a switching layer 44 of a variable resistance layer 40 in a set state by movement of oxygen vacancies Ov. The filaments F may have a vertically asymmetric shape. For example, in a region adjacent to the oxygen reservoir layer 50, i.e., in a region closest to the upper electrode 60, a large number of oxygen vacancies Ov may be widely distributed, and in a region farther from the oxygen reservoir layer 50, i.e., in a region adjacent to the lower electrode 30, a small number of oxygen vacancies Ov may be narrowly distributed. In comparative examples, when some oxygen vacancies Ob leave or deviate from the filaments F and move away in a lateral direction in the region adjacent to the lower electrode 30, the vertical connection of the filaments F may be discontinuously formed or the electrical connection degraded or disconnected in a region farther away from the oxygen reservoir layer 50, for example, in the region adjacent to the lower electrode 30. As a result, electrical resistance between the upper electrode 60 and the lower electrode 30 may not be sufficiently lowered. In embodiments of the disclosure, the barrier layer 43 can block lateral movement and diffusion of the deviated oxygen vacancies Ob. Thus, the filaments F can be more stably formed and maintained. A high connection/non-connection resistance ratio of the filaments F may be achieved, and switching characteristics of the switching layer 44 can be improved. In order to make the technical concepts of the present disclosure easier to understand, FIG. 7 shows that the oxygen vacancies Ob have deviated from the filaments F, but lateral spacing of the barrier layers 43 can be implemented narrowly to improve oxygen vacancy density adjacent to lower electrode 30, and the barrier layers 43 can block the oxygen vacancies Ob from deviating too far from the filaments F.

A vertical height (vertical thickness) Hb of the barrier layer 43 may be equal to or greater than 20% and equal to or less than 50% of a vertical height (vertical thickness) Hs of the switching layer 44. In an embodiment, the vertical height (thickness) Hb of the barrier layer 43 may be about 30% of the vertical height (thickness) Hs of the switching layer 44.

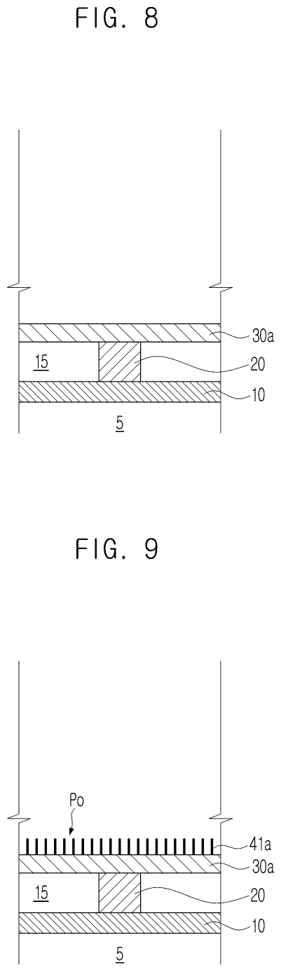

FIGS. 8 to 13 are longitudinal cross-sectional views illustrating a method of forming a memory cell structure of a semiconductor memory device according to an embodiment of the present disclosure. Referring to FIG. 8, a method of forming a memory cell structure of a semiconductor memory device may include forming an underlying layer 5, forming a lower interconnection line 10 on the underlying layer 5, forming a lower interlayer insulating layer 15 and a lower contact plug 20 on the lower interconnection line 10, and forming a lower electrode material layer 30a on the lower interlayer insulating layer 15 and the lower contact plug 20. Forming the underlying layer 5 may include forming a silicon oxide-based insulating layer or a silicon nitride-based insulating layer on a substrate by performing a deposition process. The substrate may include a silicon wafer. Forming the lower interconnection line 10 may include depositing a lower interconnection line material layer on the underlying layer 5 by performing a deposition process, and forming a plurality of conductive interconnections extending in a horizontal direction by performing a photolithography process and a patterning process. The lower interconnection line 10 may include a conductive material. For example, the lower interconnection line 10 may include at least one of doped silicon, metal, metal silicide, metal compound, or metal alloy. Forming the lower interlayer insulating layer 15 may include forming an insulating layer such as a silicon oxide based insulating layer on the underlying layer 5 and the lower interconnection line 10 by performing a deposition process. Forming the lower contact plug 20 may include performing a photolithography process and an etching process to form a contact hole vertically penetrating the lower interlayer insulating layer 15 and exposing the lower interconnection line 10, performing a filling process to fill the contact hole with a conductor, and performing a planarization process, i.e., a chemical mechanical polishing (CMP) process, to co-planarize upper surfaces of the lower contact plug 20 and the lower interlayer insulating layer 15. The lower contact plug 20 may include at least one of the conductive elements as mentioned above. Forming the lower electrode material layer 30a may include performing a deposition process to form a metal layer or a metal nitride layer. The lower electrode material layer 30a may include a diffusion barrier layer for blocking diffusion of oxygen atoms or oxygen ions. For example, the lower electrode material layer 30a may include at least one of a metal such as tungsten or a metal nitride such as titanium nitride.

Referring to FIG. 9, the method may further include forming a barrier framework material layer 41a having a plurality of pores Po on the lower electrode material layer 30a. The barrier framework material layer 41a may be understood with reference to barrier framework layer 41 in FIGS. 2B, 3A and 3B, 4A and 4B, and FIGS. 5A and 5B.

Referring to FIG. 10, the method may further include forming a barrier sidewall material layer 42a on sidewalls of the barrier framework material layer 41a. A barrier material layer 43a including the barrier framework material layer 41a and the barrier sidewall material layer 42a may be formed. Forming the barrier sidewall material layer 42a may include performing a deposition process to conformally form a barrier sidewall material layer 42a on sidewalls and upper ends of the barrier framework material layer 41a and the lower electrode material layer 30a exposed in the pores Po, and performing an anisotropic etching process such as etch-back to remove the barrier sidewall material layer 42a on the upper surfaces of the lower electrode material layer 30a. The upper surface of the lower electrode material layer 30a may be exposed again in the pores Po. The barrier sidewall material layer 42a on upper ends of the barrier framework material layer 41a may also be removed. The barrier sidewall material layer 42a on the sidewalls of the barrier framework material layer 41a may remain after the etching processes. In another embodiment, the barrier sidewall material layer 42a on the upper ends of the barrier framework material layer 41a may also partially retained after the etching processes.

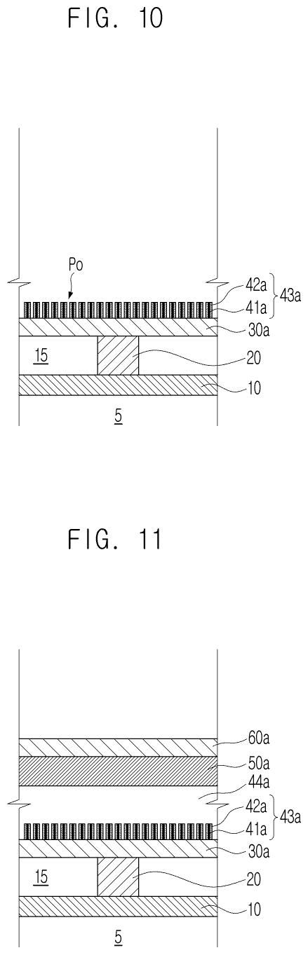

Referring to FIG. 11, the method may include performing deposition processes to form a switching material layer 44a on the lower electrode material layer 30a and the barrier material layer 43a, an oxygen reservoir material layer 50a on the switching material layer 44a, and an upper electrode material layer 60a on the oxygen reservoir material layer 50a. The switching material layer 44a may completely fill the pores Po.

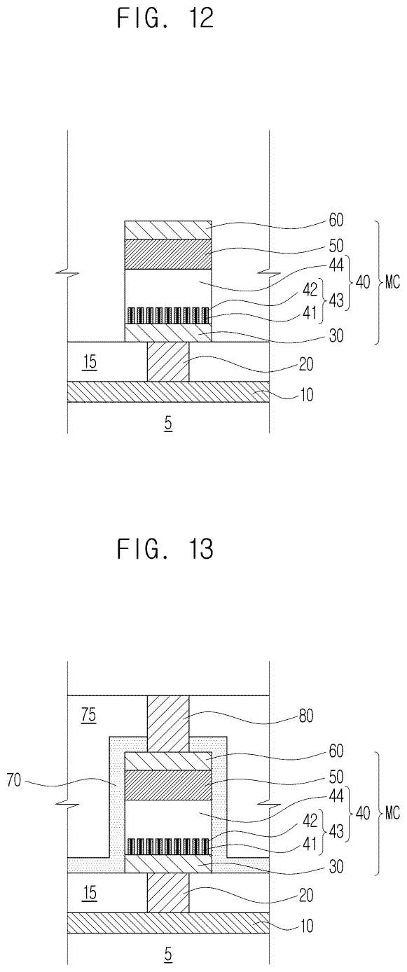

Referring to FIG. 12, the method may further include forming a memory cell MC by patterning the upper electrode material layer 60a, the oxygen reservoir material layer 50a, the variable resistance material layer 40a, and the lower electrode material layer 30a by performing a patterning process. The resulting memory cell MC may include a lower electrode 30, a variable resistance layer 40, an oxygen reservoir layer 50, and an upper electrode 60. The variable resistance layer 40 may include a barrier layer 43 and a switching layer 44. The barrier layer 43 may include a barrier framework layer 41 and a barrier sidewall layer 42.

Referring to FIG. 13, the method may further include forming a spacer layer 70, an upper interlayer insulating layer 75, and an upper contact plug 80. Forming the spacer layer 70 may include performing a deposition process to conformally form a spacer material on the sidewalls and an upper surface of the memory cell MC. Forming the upper interlayer insulating layer 75 may include forming an insulating material covering the memory cell MC and the spacer layer 70 by performing a deposition process. Forming the upper contact plug 80 may include performing a photolithography process and an etching process to form a hole vertically penetrating the upper interlayer insulating layer 75 and the spacer layer 70 to expose an upper surface of the upper electrode 60, performing a filling process to fill the hole with a conductive material, and performing a planarization process such as CMP to form coplanar upper surfaces of the upper interlayer insulating layer 75 and the upper contact plug 80.

Thereafter, referring to FIG. 2A, the method may further include forming an upper interconnection line 90 on the upper surfaces of the upper interlayer insulating layer 75 and the upper contact plug 80.

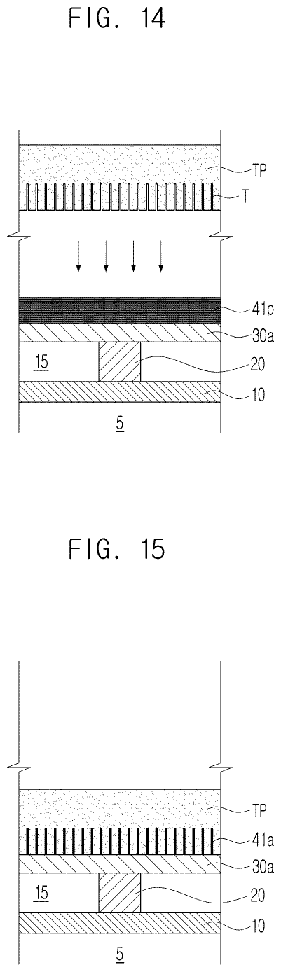

FIGS. 14 to 16 are longitudinal cross-sectional views illustrating a method of forming a memory cell structure of a semiconductor memory device according to an embodiment of the present disclosure.

Referring to FIG. 14, a method of forming a semiconductor memory device may include forming a lower interconnection line 10, a lower interlayer insulating layer 15, a lower contact plug 20, and a lower electrode material layer 30a on an underlying layer 5, and forming a preliminary barrier framework material layer 41p on the lower electrode material layer 30a. The preliminary barrier framework material layer 41p may include a material layer that does not include a framework structure. For example, the preliminary barrier framework material layer 41p may include a polymer material layer such as a polymethylmethacrylate (PMMA) layer or a block co-polymer layer. The method may further include preparing a frame template TP. The frame template TP may include trenches T for forming a framework structure. The frame template TP may include a hard material such as a metal or inorganic material.

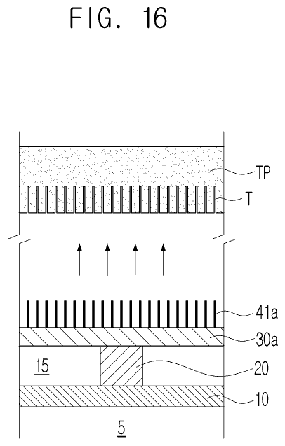

Referring to FIG. 15, the method may further include pressing the frame template TP into the preliminary barrier framework material layer 41p. Portions of the preliminary barrier framework material layer 41p may remain in the trenches T of the frame template TP.

Referring to FIG. 16, the method may further include molding the preliminary barrier framework material layer 41p into a barrier framework material layer 41a by lifting and removing the frame template TP.

Thereafter, the method may further include performing the processes described with reference to FIGS. 10 to 13 to form the memory cell structure shown in FIG. 2A.

According to the embodiments of the present disclosure, the lateral movement or diffusion of the oxygen vacancies can be prevented, the conductive filament can be maintained, the resistance of the variable resistance layer can be maintained for a longer time, and the data retention property of the memory cell can be improved.

While the present disclosure has been described with respect to some specific embodiments, it will be apparent to those skilled in the art that various changes and modifications may be made without departing from the spirit and scope of the disclosure as defined in the following claims.

What is claimed is:

1. A semiconductor device comprising:
a memory cell, wherein the memory cell includes:
a lower electrode;
a variable resistance layer over the lower electrode;
an oxygen reservoir layer over the variable resistance layer; and
an upper electrode over the oxygen reservoir layer,
wherein the variable resistance layer includes:
a barrier layer including a barrier framework layer having pores and a barrier sidewall layer conformally disposed on sidewalls of the barrier framework layer; and
a switching layer
disposed over the barrier layer and in the pores.

2. The semiconductor device of claim 1, wherein:
in a top view, the barrier framework layer has a hexagonal honeycomb shape, and
the barrier sidewall layer includes a silicon nitride layer.

3. The semiconductor device of claim 2, wherein:
the barrier framework layer includes metal nodes and organic ligands,
each metal node includes at least one of cobalt, nickel, copper, palladium, platinum, iron, or manganese, and
each organic ligand includes at least one of hexahydroxytriphenylene, hexasulfurotriphenylene, hexaiminotriphenylene, hexahydroxybenzene, hexasulfurobenzene, and hexaiminobenzene.

4. The semiconductor device of claim 1,
wherein, in a top view, the pores of the barrier framework layer arrayed in offset rows.

5. The semiconductor device of claim 4,
wherein the barrier framework layer includes one of a polymethylmethacrylate (PMMA) layer or a block-copolymer layer.

6. The semiconductor device of claim 1,
wherein a vertical thickness of the barrier framework layer is equal to or greater than 20% to equal to or less than 50% of a vertical thickness of the switching layer.

7. The semiconductor device of claim 1,
wherein an upper end of the barrier framework layer is exposed and not covered by the barrier sidewall layer.

8. The semiconductor device of claim 1,
wherein the switching layer includes a metal oxide layer.

9. The semiconductor device of claim 1,
wherein the oxygen reservoir layer includes a metal layer.

10. The semiconductor device of claim 1, further comprising:
a lower interconnection line extending in a first horizontal direction;
a lower contact plug electrically connecting the lower interconnection line to the lower electrode;
a spacer layer conformally disposed on sidewalls of the lower electrode, the variable resistance layer, the oxygen reservoir layer, and the upper electrode, and an upper surface of the upper electrode;
an upper interconnection line extending in a second horizontal direction perpendicular to the first horizontal direction; and
an upper contact plug passing through the spacer layer to electrically connect the upper electrode to the upper interconnection line.

11. The semiconductor device of claim 1,
wherein, in a set state, filaments extend vertically through the switching layer, and lower portions of the filaments are disposed in the pores.

12. The semiconductor device of claim 1,
wherein the pores expose an upper surface of the lower electrode.
